(19) United States
(12) Patent Application Publication
(10) Pub. No.: US 2024/0113559 A1
(43) Pub. Date: Apr. 4, 2024

(54) GRAPHENE-INTEGRATED PERSONAL ENERGY HARVESTING SYSTEM FOR ELECTRONIC DEVICES

(71) Applicant: Esezobor Ebaneh, Toronto (CA)

(72) Inventor: Esezobor Ebaneh, Toronto (CA)

(21) Appl. No.: 18/536,478

(22) Filed: Dec. 12, 2023

(51) Int. Cl. H02J 50/00; H01L 31/028; H02J 7/34; H02J 7/35; H02J 50/80; H10N 10/855; H10N 30/00; H10N 30/30

(52) U.S. Cl. CPC H02J 50/001; H01L 31/028; H02J 7/345; H02J 7/35; H02J 50/005; H02J 50/80; H10N 10/855; H10N 30/1061; H10N 30/30; H02J 2207/50; H02J 2300/22

(57) ABSTRACT

The invention relates to a personal energy harvesting system. This innovative system seamlessly incorporates graphene technology to optimize energy harvesting, storage, and utilization. By harnessing energy from diverse sources such as body movement, ambient heat, and light, the PEHS ensures a constant and sustainable power supply. The integration of graphene-enhanced supercapacitors enables efficient energy storage, providing a reliable reservoir for sustained use. Moreover, the system offers wireless charging capabilities, enabling the convenient powering of electronic devices. With its versatile design and global applicability, the PEHS represents a significant leap forward in personal energy solutions, promising enhanced sustainability and accessibility on a worldwide scale.

### FIELD OF THE INVENTION

The present invention relates generally to wearable energy harvesting systems and more particularly, to a personal energy harvesting system (PEHS) that employs graphene within its components to enhance the efficiency and capacity of energy generation and storage for the purpose of charging electronic devices.

### BACKGROUND OF THE INVENTION

The increasing need for portable electronic devices has fueled an ongoing quest for inventive and environmentally friendly energy solutions. Conventional energy harvesting methods have leveraged kinetic motion, thermal variations, and solar energy to produce power. Despite these efforts, these systems frequently encounter challenges such as suboptimal energy conversion efficiency, inadequate storage capacity, and limited resilience to the various conditions encountered in everyday use. This highlights the persistent need for advancements that can address these shortcomings, ensuring that the energy solutions for portable electronics are not only efficient but also robust and capable of withstanding the diverse and demanding situations they may encounter in real-world scenarios.

As an illustration, devices designed to harvest kinetic energy often rely on piezoelectric materials or electromagnetic induction. However, their ability to capture energy is restricted by the inherent limitations of these materials, resulting in the capture of only a fraction of the available energy. Likewise, thermoelectric generators, which aim to convert body heat into electricity, have faced challenges associated with low efficiency and elevated material costs.

In the field of solar energy harvesting, technologies utilizing flexible solar panels encounter limitations in their performance under changing light conditions and their seamless integration into wearable formats. These constraints underscore the critical need for advancements that can overcome these specific challenges associated with each energy harvesting method, fostering more efficient and versatile solutions for diverse applications.

Storing the energy obtained from harvesting poses its own set of difficulties. Conventional batteries and capacitors commonly involve a compromise between factors like energy and power density, lifecycle, and the duration required for charging. Although supercapacitors exhibit the advantage of swift charging and discharging, they haven't reached the necessary energy density for sustained usage without the need for frequent recharging. The challenge lies in finding a storage solution that seamlessly balances these key parameters, ensuring a harmonious interplay between energy density for prolonged use, rapid charging capabilities, and a lifespan that accommodates the demands of various applications. Overcoming these challenges is crucial for advancing the effectiveness and reliability of energy harvesting systems in real-world scenarios.

Past endeavors aimed at developing effective Personal Energy Harvesting Systems (PEHS) have not maximized the capabilities of advanced materials to address the mentioned constraints. Notably, there has been a deficiency in incorporating innovative materials that can function across a wider range of energy harvesting techniques, simultaneously offering improved storage capabilities. The existing limitations persist due to a historical oversight in fully leveraging the potential of cutting-edge materials, which possess the versatility required to enhance the efficiency of diverse energy harvesting methods. A critical gap exists in seamlessly integrating these new materials to create a unified and comprehensive solution that not only captures energy effectively but also stores it efficiently, thereby overcoming the limitations of previous PEHS designs.

Graphene, an extraordinary two-dimensional carbon structure, boasts outstanding qualities such as high electrical and thermal conductivity, mechanical robustness, and flexibility, making it a highly promising material for a range of technological applications. However, the full scope of graphene's potential remains largely untapped, especially in the realm of wearable energy systems. Current implementations have not fully harnessed graphene's capabilities, particularly in the context of creating an integrated wearable energy system that maximizes its advantages for multi-source energy harvesting and efficient energy storage within a single, wearable platform.

Exploring graphene's integration into wearable energy systems opens up new possibilities for enhanced performance and versatility. The intrinsic properties of graphene, such as its excellent electrical conductivity, make it an ideal candidate for efficiently capturing energy from various sources, including body movements, heat, and ambient light. By optimizing the design to leverage these distinctive properties, a graphene-enhanced wearable energy system can potentially revolutionize the landscape of portable power solutions, offering improved energy harvesting capabilities and storage efficiency. This exploration represents a significant advancement in realizing the untapped potential of graphene within the wearable technology domain.

Moreover, within the current landscape, although there are products that incorporate certain elements of energy harvesting, there exists a noticeable gap in the market for a comprehensive solution. What is lacking is a holistic and adaptable system that not only addresses various energy harvesting methods but is also modular and customizable. This kind of solution would seamlessly integrate into the user's lifestyle, offering a tailored and user-friendly experience. The market deficiency lies in the absence of a versatile system that not only caters to diverse energy sources but also aligns with individual preferences and needs. Such a holistic solution would not only meet the immediate power needs of electronic devices but also make a tangible and positive contribution to sustainable energy practices, aligning with the growing demand for personalized and eco-friendly technologies in today's dynamic consumer landscape.

### SUMMARY OF THE INVENTION

To address the foregoing problems, in whole or in part, and/or other problems that may have been observed by persons skilled in the art, the present disclosure provides compositions and methods as described by way of example as set forth below.

The primary objective of the present invention is to rectify the existing shortcomings by introducing a Personal Energy Harvesting System (PEHS) that strategically incorporates graphene. The integration of graphene is intended to bring about a substantial enhancement in the efficiency of energy harvesting, specifically from diverse sources, while concurrently boosting the system's energy storage capacity and speed. By leveraging the unique properties of graphene, this invention seeks to overcome the limitations observed in prior designs and establish a new benchmark for energy autonomy in electronic devices.

The present invention discloses Personal Energy Harvesting System (PEHS) that incorporates graphene, offering a forward-thinking solution for the sustainable and efficient management of energy within the realm of wearable technology. Specifically crafted to cater to electronic devices, this system introduces an innovative approach to capturing, storing, and utilizing energy seamlessly through wearables. The overarching objective is to confront and surmount the prevalent challenges witnessed in conventional personal energy harvesters, which are often plagued by issues such as suboptimal efficiency, constrained storage capacity, and insufficient durability.

By integrating graphene, a two-dimensional carbon material with exceptional properties like high conductivity and mechanical strength, the PEHS aspires to redefine the standards of personal energy solutions. Through this inventive design, the system seeks to establish a new benchmark in terms of energy efficiency, storage capacity, and robustness, ultimately ushering in a more sustainable and reliable era in wearable technology.

Central to the core of this invention lies the utilization of graphene, a material celebrated for its extraordinary attributes encompassing exceptional electrical conductivity, thermal properties, mechanical strength, and flexibility. The innovation at play involves seamlessly integrating graphene into pivotal elements of the Personal Energy Harvesting System (PEHS), such as flexible solar panels, thermoelectric generators, and kinetic energy harvesters. This strategic incorporation of graphene serves as a catalyst for transformative improvements in the efficiency of energy conversion, particularly from ambient sources like body heat, movement, and light.

By infusing graphene into these key components, the invention capitalizes on the material's unique properties to enhance the performance of each energy harvesting method. Flexible solar panels gain heightened efficiency, thermoelectric generators experience improved conversion rates from body heat, and kinetic energy harvesters see enhanced capabilities due to graphene's exceptional conductivity. The result is a holistic and efficient energy harvesting system that taps into diverse ambient sources, marking a significant leap forward in the landscape of wearable technology and sustainable energy practices.

Moreover, the invention introduces the integration of graphene-enhanced supercapacitors for energy storage, capitalizing on graphene's remarkable characteristics, including its high surface area and exceptional electrical properties. This strategic integration results in supercapacitors that boast greater energy density and swifter charging capabilities when juxtaposed with conventional energy storage solutions. The utilization of graphene enables the supercapacitors to store and release energy efficiently, addressing issues commonly associated with slower charging times and limited storage capacity in traditional solutions.

These graphene-enhanced supercapacitors are purposefully designed to be lightweight and seamlessly incorporated into various wearable forms such as wristbands, clothing, and shoes. This design approach ensures that users benefit from a convenient, unobtrusive, and powerful source of energy while on the move. By combining the advantages of graphene-enhanced supercapacitors with wearable technology, the invention not only enhances the overall efficiency of the energy system but also transforms the way users interact with and harness energy in their daily lives.

The system's distinctive modularity and customizable features empower users to tailor their energy solutions by selecting and combining different energy harvesting modules, aligning with their unique lifestyles and preferences. This approach facilitates a highly personalized energy generation and consumption experience, where users can choose the specific modules that best suit their needs. This adaptability is crucial for accommodating diverse energy sources and usage patterns, ensuring that the Personal Energy Harvesting System (PEHS) seamlessly integrates into various contexts.

Moreover, the PEHS incorporates an Internet of Things (IoT) connectivity feature, establishing a link with a dedicated smartphone application. This application serves as a control center, offering users real-time monitoring capabilities for their energy generation and storage. The app goes beyond mere observation, providing insightful recommendations to optimize energy usage based on individual patterns and preferences. By merging modularity with smart connectivity, the PEHS not only enhances user control over their energy solutions but also promotes a more sustainable and efficient approach to energy consumption in alignment with individual needs and behaviors.

The design philosophy of the EcoCharge system centers around a paramount commitment to sustainability, evident in the meticulous selection of materials that includes advanced and eco-friendly graphene composites. The incorporation of these materials extends beyond merely enhancing the system's performance; it underscores a conscientious effort to align with global environmental standards and meet consumer expectations for green technology products.

The choice of advanced graphene composites represents a forward-thinking approach to material selection, as graphene is known for its eco-friendly characteristics. This ensures that the EcoCharge system not only delivers on its functional objectives but also adheres to a broader eco-conscious ethos. By integrating materials that are both technologically sophisticated and environmentally responsible, the EcoCharge system sets a noteworthy precedent in the pursuit of sustainable design within the realm of energy harvesting and wearable technology. This eco-centric focus not only caters to the present demand for green solutions but also positions the system as a conscientious choice for environmentally aware consumers.

The innovation extends to the intelligent energy management features of the PEHS. The incorporated IoT platform doesn't just oversee the generation and storage of energy but also manages the distribution of power to different devices. This optimization of charging cycles plays a crucial role in extending the lifespan of the supercapacitors. Additionally, the application offers a user-friendly interface, educating consumers about their energy consumption patterns and encouraging behaviors that promote energy conservation.

In addition to its technological advancements, this invention considers an array of form factors for the wearables, recognizing the need to cater to diverse fashion preferences and functional necessities. The unique properties of graphene composites provide a high degree of flexibility, enabling the EcoCharge wearables to strike a balance between being unobtrusive and stylish. This flexibility in design not only enhances the aesthetic appeal of the wearables but also ensures that they remain resilient enough to withstand the demands of daily use in various climates and environments.

The incorporation of graphene allows for a harmonious blend of functionality and fashion, breaking away from the conventional notion that advanced technology must compromise on aesthetics. This forward-thinking approach to wearable design acknowledges the importance of user preferences, offering a range of options that not only align with diverse fashion sensibilities but also seamlessly integrate into different lifestyles and settings. As a result, the EcoCharge wearables transcend the boundaries of traditional design, presenting a versatile and adaptable solution that enhances both style and substance in the realm of wearable technology.

The modular feature of the PEHS stands out, enabling effortless system expansion or upgrades. Users have the flexibility to incorporate extra energy harvesting modules, swap out worn-out components, or integrate the latest advancements without the necessity of buying an entirely new product. This approach not only minimizes electronic waste but also fosters a circular economy, emphasizing sustainability through the efficient use and reuse of components.

Beyond these advantages tailored to user needs, the EcoCharge system prioritizes simplicity in manufacturing and scalability. The incorporation of graphene, while boosting product performance, doesn't overly complicate the manufacturing procedures, facilitating efficient scaling of production to meet worldwide demand.

Acknowledging the diverse energy requirements and availability in different geographic locations, the invention incorporates customizable settings. These settings can adapt the energy harvesting and storage mechanisms to optimize efficiency based on the specific conditions, whether it be in sun-drenched areas conducive to solar energy or regions abundant in kinetic and thermal energy.

The features of the invention which are believed to be novel are particularly pointed out in the specification. The present invention now will be described more fully hereinafter with reference to the accompanying drawings, which are intended to be read in conjunction with both this summary, the detailed description and any preferred and/or particular embodiments specifically discussed or otherwise disclosed. This invention may, however, be embodied in many different forms and should not be construed as limited to the embodiments set forth herein; rather, these embodiments are provided by way of illustration only and so that this disclosure will be thorough, complete and will fully convey the full scope of the invention to those skilled in the art.

### BRIEF DESCRIPTION OF THE DRAWINGS

The preferred embodiments of the invention will hereinafter be described in conjunction with the appended drawings provided to illustrate and not to limit the invention, where like designations denote like elements, and in which:

FIG. 1A illustrates a front perspective view of an example personal energy harvesting system including a wearable cap, at least one energy harvesting device, at least one energy storage device and a charging module, according to an embodiment of the present invention.

FIG. 1B illustrates a front perspective view of an example personal energy harvesting system including a wearable wristband, at least one energy harvesting device, at least one energy storage device and a charging module, according to an embodiment of the present invention.

FIG. 1C illustrates a front perspective view of an example personal energy harvesting system including an umbrella, at least one energy harvesting device, at least one energy storage device and a charging module, according to an embodiment of the present invention.

FIG. 1D illustrates a side perspective view of an example personal energy harvesting system including a shoe, at least one energy harvesting device, at least one energy storage device and a charging module, according to an embodiment of the present invention.

FIG. 1E illustrates a side perspective view of an example personal energy harvesting system including a pet saddle, at least one energy harvesting device, at least one energy storage device and a charging module, according to an embodiment of the present invention.

Like reference numerals refer to like parts throughout the several views of the drawings.

### DETAILED DESCRIPTION OF THE DRAWINGS

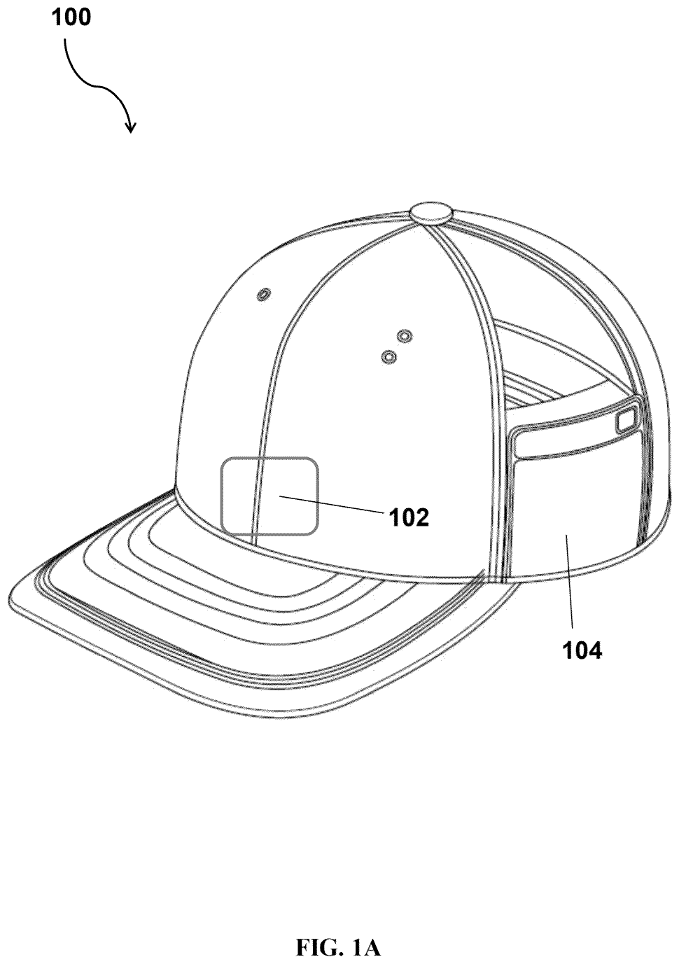

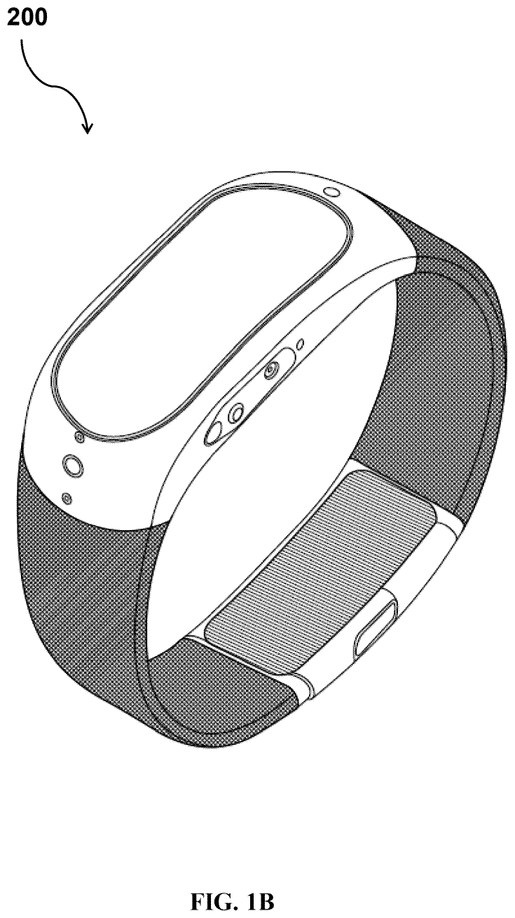

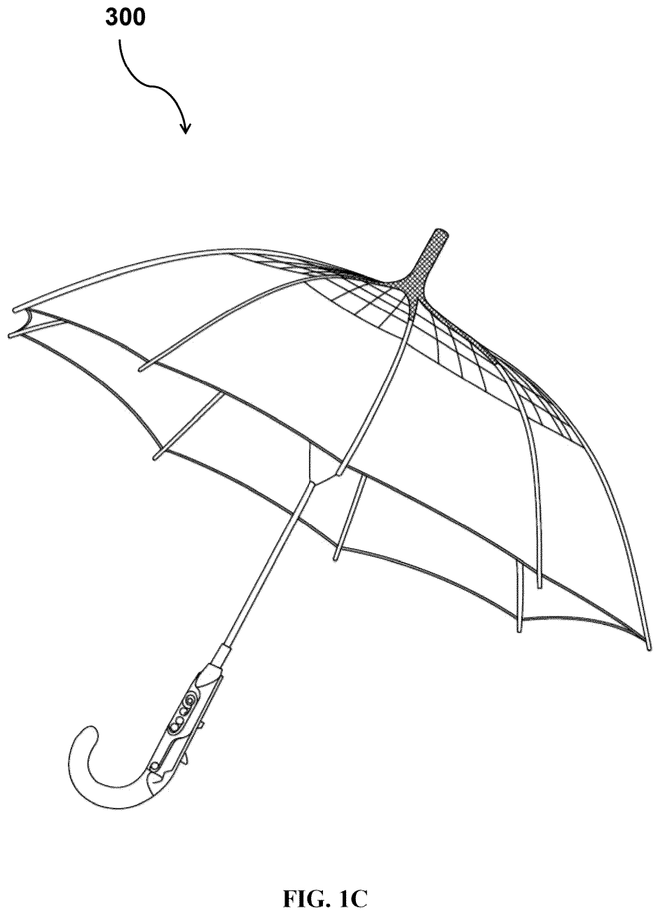

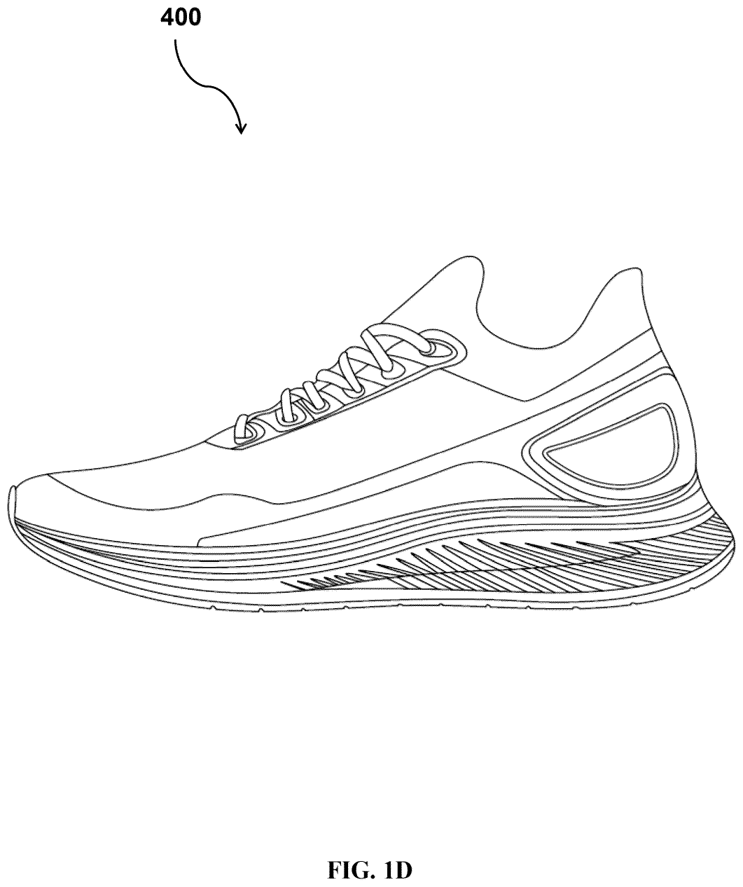

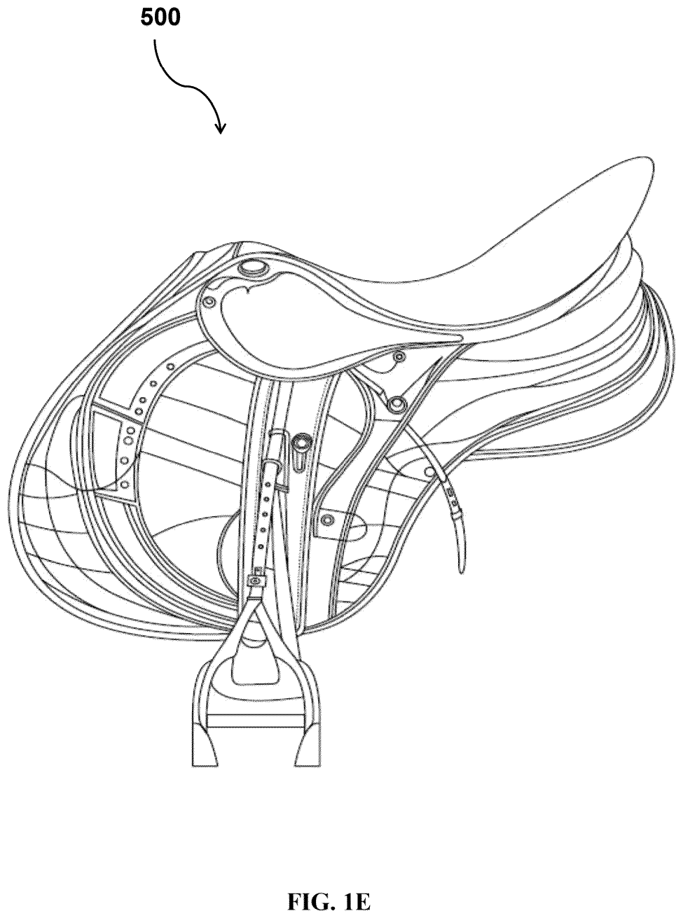

The following detailed description is merely exemplary in nature and is not intended to limit the described embodiments or the application and uses of the described embodiments. As used herein, the word “exemplary” or “illustrative” means “serving as an example, instance, or illustration.” Any implementation described herein as “exemplary” or “illustrative” is not necessarily to be construed as preferred or advantageous over other implementations. All of the implementations described below are exemplary implementations provided to enable persons skilled in the art to make or use the embodiments of the disclosure and are not intended to limit the scope of the disclosure, which is defined by the claims. For purposes of description herein, the terms “upper”, “lower”, “left”, “rear”, “right”, “front”, “vertical”, “horizontal”, and derivatives thereof shall relate to the invention as oriented in FIG. 1. Furthermore, there is no intention to be bound by any expressed or implied theory presented in the preceding technical field, background, brief summary or the following detailed description. It is also to be understood that the specific devices and processes illustrated in the attached drawings, and described in the following specification, are simply exemplary embodiments of the inventive concepts defined in the appended claims. Hence, specific dimensions and other physical characteristics relating to the embodiments disclosed herein are not to be considered as limiting, unless the claims expressly state otherwise.

The subject matter of the present invention now will be described more fully hereinafter with reference to the accompanying drawings, in which some, but not all embodiments of the subject matter of the present invention are shown. Like numbers refer to like elements throughout. The subject matter of the present invention may be embodied in many different forms and should not be construed as limited to the embodiments set forth herein; rather, these embodiments are provided so that this disclosure will satisfy applicable legal requirements. Indeed, many modifications and other embodiments of the subject matter of the present invention set forth herein will come to mind to one skilled in the art to which the subject matter of the present invention pertains having the benefit of the teachings presented in the foregoing descriptions and the associated drawings. All illustrations of the drawings are for the purpose of describing selected versions of the present invention and are not intended to limit the scope of the present invention. Therefore, it is to be understood that the subject matter of the present invention is not to be limited to the specific embodiments disclosed and that modifications and other embodiments are intended to be included within the scope of the appended claims.

Shown throughout the FIGURES, the present invention is directed to an unique personal energy harvesting system and method, enabling users to produce electricity from their daily movements and subsequently utilize it for charging external electronic devices like smartphones, smartwatches, and headphones. This system actively promotes sustainable energy generation, empowering users to derive power from routine activities. Consequently, it diminishes dependence on traditional, non-renewable energy sources, thereby reducing users' carbon footprints. By providing a user-friendly and environmentally conscious charging solution for electronic devices, the personal energy harvesting system fosters the adoption of greener practices and contributes to a more sustainable future. Moreover, the system tackles the issue of electronic device waste by incorporating sustainable materials and adopting a modular design that encourages customization and upgradability. This design approach not only extends the lifespan of the devices but also minimizes overall waste.

The disclosed system may utilize one or more of energy harvesting devices including modular solar panel designs, advanced material science, IoT (Internet of Things) connectivity, software applications, artificial intelligence (AI) integration, energy sharing, health and wellness monitoring, gamification, wearable customization, smart grid integration, emergency power backup, environmental impact tracking, wireless energy transfer, energy trading marketplaces, and energy conversion modules to provide a scalable and environmentally friendly solution.

The integration of IoT and AI enhances connectivity and intelligence, fostering a more responsive and efficient energy harvesting process. Additionally, features such as energy sharing, health monitoring, and gamification not only enhance user experience but also encourage sustainable practices. The inclusion of smart grid integration, emergency power backup, and wireless energy transfer further broadens the system's applicability and resilience, while environmental impact tracking and energy trading marketplaces underscore a commitment to environmental consciousness and efficiency in resource utilization. In essence, this system amalgamates a diverse set of technologies to create a scalable, adaptive, and environmentally responsible energy solution.

The present invention leverages the extraordinary electrical conductivity and mechanical characteristics of graphene to enhance the process of harvesting energy from both environmental and bodily sources. Graphene is incorporated into flexible solar panels, thermoelectric generators, and kinetic energy harvesters through the following ways:

Solar panels: For the solar panels, the integration of graphene involves the incorporation of graphene-infused photovoltaic materials. This infusion enhances the light-capturing capabilities of the solar panels, enabling them to capture a broader spectrum of light when compared to conventional solar cells. The inclusion of graphene in the composition optimizes the efficiency of light absorption, contributing to increased energy conversion.

Additionally, the flexibility of these graphene-enhanced solar panels is a key feature. This flexibility allows for the seamless integration of the panels into the fabric of clothing or various accessories. This innovative design choice not only enhances the aesthetic appeal of wearable technology but also ensures practicality by enabling users to incorporate solar panels into their attire, thereby enhancing the overall adaptability and user-friendliness of the energy harvesting system. This integration into clothing and accessories represents a forward-thinking approach that aligns with the evolving landscape of wearable technology.

Thermoelectric Generators: In the case of thermoelectric generators, the incorporation of graphene is focused on enhancing the materials used in the generators. Specifically, graphene-enhanced materials are employed to improve the Seebeck coefficient, a critical factor in the process of converting temperature differences directly into electric voltage. The utilization of graphene in these materials contributes to optimizing the efficiency of the thermoelectric conversion, ensuring a more effective harnessing of body heat to generate electric power.

Moreover, the thin and flexible nature of these graphene-enhanced thermoelectric generators is noteworthy. This design characteristic allows for their seamless integration into various points of wear, such as the inner lining of clothing or the underside of a wristband. By being flexible and adaptable, these generators can conform to the contours of the body, ensuring optimal contact with the heat source and, consequently, efficient capture of body heat. This innovative approach not only enhances the overall performance of the energy harvesting system but also promotes user comfort and convenience by enabling unobtrusive integration into various wearable items.

Kinetic Energy Harvesters: In the field of kinetic energy harvesters, the design involves the utilization of piezoelectric materials in conjunction with graphene. These kinetic devices operate by harnessing the inherent properties of piezoelectric materials, which can generate electricity in response to mechanical stress. The integration of graphene into this system plays a crucial role in facilitating the efficient transfer of the generated energy with minimal loss.

Piezoelectric materials, when subjected to mechanical stress, generate electric charges due to their unique crystalline structure. By combining these materials with graphene, which is renowned for its exceptional electrical conductivity, the kinetic energy harvesters benefit from an enhanced ability to transfer the generated electric charges effectively. The inclusion of graphene in this context ensures that the energy captured from kinetic movements, such as walking or body motion, is efficiently transferred and stored for subsequent use, contributing to the overall efficacy of the kinetic energy harvesting process.

This synergistic combination of piezoelectric materials and graphene not only improves the efficiency of energy conversion but also underscores the innovation in the design of wearable technology. The result is a kinetic energy harvesting system that optimally captures and utilizes mechanical energy, showcasing the potential for sustainable and self-sufficient power sources in the field of wearable electronics.

In an embodiment, the energy captured through harvesting processes is effectively stored within graphene supercapacitors seamlessly integrated into the wearable items. The incorporation of graphene into these supercapacitors offers several advantages, enhancing their overall performance:

High Energy Density: Graphene's high surface area allows the supercapacitors to store a substantial amount of energy relative to their size. This feature ensures that the wearable items can accommodate a significant energy reservoir, providing sustained power for connected electronic devices.

Rapid Charging and Discharging: Thanks to graphene's excellent conductivity, the supercapacitors enable swift charging and discharging cycles. This attribute facilitates the rapid storage of energy and ensures quick and efficient power delivery to the electronic devices integrated into the wearables.

Longevity: The durability of graphene contributes to the extended lifespan of the supercapacitors. These components can endure a large number of charge and discharge cycles without undergoing significant degradation, ensuring reliable and sustained performance over an extended period.

The integration of graphene into the supercapacitors not only optimizes their functionality but also establishes a robust foundation for the wearable energy system. This innovative design choice reflects a commitment to efficiency, reliability, and longevity in providing a sustainable power solution for electronic devices seamlessly incorporated into wearable technology.

In an embodiment, the wearables are meticulously designed to embody characteristics of lightness, comfort, and robustness. Their construction involves the integration of graphene-enhanced fibers, imparting a range of advantages to the wearable items:

Durability: The incorporation of graphene significantly enhances tensile strength, bolstering the wearables' resistance to tearing and damage. This durability ensures that the wearables can withstand the rigors of daily use, contributing to an extended lifespan and sustained performance.

Flexibility: Graphene-enhanced fibers maintain flexibility, a pivotal characteristic for ensuring wearer comfort. This flexibility not only enhances the ergonomic design of the wearables but also facilitates the seamless integration of energy-harvesting technologies without compromising user comfort.

Thermal Regulation: Leveraging graphene's thermal conductivity, the wearables excel in dissipating heat generated by the supercapacitors and electronic components. This thermal regulation feature contributes to maintaining a stable temperature, ensuring user comfort and the optimal functioning of the embedded technologies.

In addition to these physical attributes, the Personal Energy Harvesting System (PEHS) incorporates advanced IoT connectivity for real-time monitoring and control, providing a comprehensive energy management experience:

Energy Monitoring: The system's IoT connectivity enables real-time tracking of energy generation from each module, offering insights into the performance of individual components and the overall system. This monitoring capability ensures users stay informed about the energy harvest and utilization patterns.

Device Charging Management: The PEHS intelligently manages power distribution to optimize the charging of connected devices. This includes adapting to user patterns and priority settings, ensuring efficient energy allocation and utilization based on individual preferences and needs.

Software Integration: The associated application serves as an interface for users to interact with the PEHS, providing comprehensive energy management capabilities. This includes analytics on energy generation, consumption, and recommendations for optimizing energy usage. The user-friendly application enhances the overall accessibility and control users have over their wearable energy system, contributing to a seamless and personalized experience.

The production process for the graphene-integrated components has been meticulously designed to ensure scalability, allowing for efficient and large-scale manufacturing. This involves a series of well-thought-out methods throughout the production chain.

Graphene Production is the initial step, and it relies on established techniques such as chemical vapor deposition (CVD) or other scalable methods. These processes aim to yield high-quality graphene, a critical factor in enhancing the overall performance of the wearable devices.

Moving on to Component Fabrication, the integration of graphene into materials and components is facilitated through advanced techniques like roll-to-roll processing and 3D printing. These methods are chosen for their scalability, enabling the mass production of modular parts with the integrated graphene. This step ensures uniformity and precision in incorporating graphene into various wearable components.

The final stage is Assembly, where automated assembly lines play a pivotal role in ensuring efficiency. These assembly lines are designed to seamlessly integrate the graphene components into the wearable devices. The automation aspect not only streamlines the production process but also contributes to maintaining consistency in the quality of the final products.

Collectively, these production methods underscore the commitment to scalability, allowing for the efficient and widespread manufacturing of wearable devices with integrated graphene components. This approach not only ensures the accessibility of advanced technology to a broader audience but also positions the innovation at the forefront of sustainable and scalable production practices in the wearable technology industry.

The environmental benefits of the system are comprehensively addressed, emphasizing a commitment to sustainability across various aspects of the product life cycle. The focus begins with Sustainable Production methods, where the production of graphene and other components is executed with a keen awareness of minimizing environmental impact. By adopting practices that prioritize sustainability, the manufacturing process aligns with the broader goals of reducing ecological footprints associated with technological advancements

The system's impact on reducing Electronic Waste is a noteworthy aspect of its design philosophy. The modular structure allows for individual parts to be replaced or upgraded without necessitating the disposal of the entire device. This approach not only promotes longevity and cost-effectiveness for users but significantly contributes to minimizing electronic waste. By embracing a modular design, the system aligns with the principles of a circular economy, encouraging resource efficiency and waste reduction.

Furthermore, the consideration for Recyclability extends to the end-of-life phase of the product. This involves evaluating the recyclability of the graphene components and associated materials. By prioritizing recyclability, the system takes a proactive stance in ensuring responsible waste management. This multi-faceted approach to environmental sustainability, from production to end-of-life considerations, positions the system as a conscientious solution within the landscape of wearable technology, addressing critical environmental concerns and contributing to a more sustainable technological future.

The disclosed personal energy harvesting system adheres to a commitment to environmental sustainability through a meticulous selection of materials and manufacturing processes. The choice of materials and production methods is specifically curated to minimize environmental impact, aligning with eco-conscious principles. Additionally, the system exhibits a forward-thinking approach to electronic waste management. By design, it enables the replacement and upgrade of individual components without the requirement to discard the entire system. This intentional modularity not only extends the overall lifespan of the energy harvesting system but also significantly contributes to the reduction of electronic waste, showcasing a dedication to environmental responsibility and resource efficiency.

In accordance with an embodiment of the present invention, there is shown in FIG. 1A an example embodiment of the personal energy harvesting system. As shown in FIG. 1A and as discussed above, the personal energy harvesting system may include a wearable cap for wearing by a user, at least one energy harvesting device, at least one energy storage device, and a charging module.

In some embodiments, as shown in FIG. 1A, the wearable may include a cap 100. However, it's important to note that the wearable is not confined to a cap 100 or any specific hat configuration. The wearable is envisioned to encompass any item that a user can wear or carry. This user may be a human and/or an animal. For instance, the wearable could encompass various types of headgear such as hats, scarves, necklaces or chest-worn devices, gloves, ear warmers, headbands, leggings or pants, suspenders, harnesses, eyeglasses or sunglasses, knee braces, elbow braces, swimsuits or wetsuits, shoulder or chest straps, umbrellas, earmuffs or headphones, gaiters, posture support braces, pet collars, corresponding owner bracelets, pet harnesses, corresponding owner's belt, pet vests, corresponding owner's jackets, pet leashes, corresponding owner's wristbands, pet booties, corresponding owner shoes, pet saddles, corresponding owner's backpack, and so forth.

The versatility of the wearable extends beyond traditional headwear to include a wide array of items that can be worn or carried by both humans and animals. This expansive range of possibilities demonstrates the adaptability and broad applicability of the wearable concept within the scope of the disclosed embodiments.

As shown, the at least one energy harvesting device may be integrated into the wearable, configured to harvest energy from one or more sources and generate electricity therefrom. For example, the at least one energy harvesting device may include various devices used to capture energy from a variety of sources, including (but not limited to) body heat, movement and ambient light. As such, as shown in FIG. 1A, the at least one energy harvesting device may include flexible solar panels, thermoelectric generators, and kinetic energy generators seamlessly integrated into the wearable.

In practical terms, the energy harvesting device encompasses a range of technologies that collectively contribute to its capacity for energy extraction. Flexible solar panels harness energy from sunlight, thermoelectric generators capture and convert thermal gradients (utilizing body heat, for instance), and kinetic energy generators tap into movement-related energy sources. The seamless integration of these technologies into the wearable enhances its overall efficiency, enabling a holistic approach to energy harvesting. This multifaceted design not only showcases the adaptability of the energy harvesting device but also underscores its potential to derive energy from a combination of sources, offering a comprehensive and sustainable solution within the wearable context.

The solar panels play a pivotal role in capturing ambient light and converting it into electricity. These solar panels are thoughtfully designed to be flexible, lightweight, durable, and adaptable to a variety of wearable forms. Notably, some implementations introduce a modular aspect to the solar panels, providing users with the flexibility to add or remove panels based on their specific energy requirements or prevailing environmental conditions. This modular design enhances user customization and ensures optimal energy harvesting based on individual needs.

Furthermore, the thermoelectric generators within the system exploit the Seebeck effect to capture and convert body heat into electricity. These generators are strategically integrated into wearables, maximizing their exposure to and utilization of body heat for efficient energy generation. The kinetic energy generators, on the other hand, leverage mechanical energy generated from the user's movements, such as walking, running, or cycling, and convert it into electricity. This process is seamlessly integrated into various forms of wearables, catering to user preferences and ensuring adaptability.

In essence, the comprehensive design of the system encompasses solar, thermoelectric, and kinetic energy harvesting mechanisms, each strategically integrated into wearables. This approach not only underscores the system's versatility but also emphasizes user-centric features such as customization and adaptability, offering a well-rounded solution for sustainable energy generation in wearable technology.

As shown in FIG. 1A, at least one storage device may also be integrated into the wearable. Particularly, the at least one storage device may include at least one supercapacitor integrated into the wearable and configured to store the generated electricity. The at least one supercapacitor may be lightweight, have fast charging and discharging capabilities and a long operational life. Further, the charging module may be configured for connection with the at least one supercapacitor, and also to an electronic device, thereby connecting the at least one supercapacitor to the electronic device and enabling charging of the electronic device with the stored electricity in the at least one supercapacitor. Particularly, the charging module may be a universal wireless charging module enabling wireless charging of the electronic device.

Moreover, the system introduces a charging module that interfaces with the at least one supercapacitor and, concurrently, with an electronic device. This connection links the supercapacitor to the electronic device, facilitating the charging of the latter with the stored electricity within the supercapacitor. Notably, the charging module is designed to be versatile, with the capability to wirelessly charge the electronic device. This wireless charging feature adds a layer of convenience, allowing users to charge their electronic devices without the constraints of physical connectors. The integration of a universal wireless charging module further exemplifies the system's commitment to user-friendly and advanced technological solutions within the realm of wearable energy systems.

In addition, although not illustrated, the personal energy harvesting system may include IoT connectivity, software application integration, artificial intelligence (AI) integration, energy sharing, health and wellness monitoring, gamification, wearable customization, smart grid integration, emergency power backup, environmental impact tracking, wireless energy transfer, energy trading marketplaces, and energy conversion modules to provide a scalable and environmentally friendly solution.

The system's integration with IoT facilitates seamless connectivity, allowing the wearable and associated devices to communicate and exchange data. Software application integration extends the system's usability, providing users with a cohesive and user-friendly experience. The infusion of AI introduces intelligent functionalities, optimizing energy harvesting based on user behavior and environmental conditions. Energy sharing allows users to distribute excess energy within a network, fostering a collaborative approach to sustainability.

Moreover, the incorporation of health and wellness monitoring features aligns the system with broader well-being initiatives. Gamification elements add an engaging aspect, motivating users to actively participate in sustainable practices. Customization options for wearables cater to individual preferences, promoting user comfort and personalization.

The integration with smart grids establishes a connection to broader energy networks, enhancing overall efficiency. Emergency power backup features provide reliability during critical situations. Environmental impact tracking mechanisms enable users to quantify and understand the positive environmental effects of their energy-saving efforts. Wireless energy transfer capabilities eliminate the need for physical connections, enhancing user convenience. Energy trading marketplaces introduce a novel dimension, allowing users to exchange surplus energy, fostering a dynamic and community-driven energy ecosystem. Lastly, energy conversion modules ensure that harvested energy can be efficiently transformed and utilized for diverse applications, enhancing the overall versatility of the personal energy harvesting system.

Particularly, the personal energy harvesting system is designed to establish a connection with a smartphone application through the utilization of IoT technology. This connection enables users to have real-time visibility into their energy generation, storage, and usage. The smartphone application extends its functionality beyond mere monitoring, offering personalized recommendations to users. These recommendations are tailored to optimize energy harvesting and consumption patterns, taking into account the unique habits and routines of individual users. This real-time feedback and guidance contribute to fostering awareness and cultivating a more responsible approach to energy consumption among users.

Furthermore, the integration of AI algorithms within the personal energy harvesting system introduces a sophisticated layer of intelligence. The AI algorithms are instrumental in optimizing both energy harvesting and usage based on individual preferences and lifestyle patterns. For instance, the AI system can learn and adapt to the user's daily routines, subsequently suggesting ways to conserve energy or adjusting energy harvesting settings to ensure the most efficient and optimal utilization of energy resources. This personalized and adaptive approach not only enhances the overall efficiency of the energy system but also promotes a seamless integration of sustainable practices into users' daily lives, reflecting a forward-looking and user-centric design philosophy.

Moreover, the personal energy harvesting system may integrate a functionality enabling users to monitor their reduction in carbon footprint, calculated from the energy generated and utilized through the system. This tracking feature serves as a motivational tool, encouraging users to actively diminish their environmental impact. Additionally, the system may incorporate gamification elements into the energy harvesting process, enhancing engagement and providing rewards to users. For instance, users could accrue points or incentives for attaining predefined energy generation goals or for participating in energy-sharing activities with fellow users. This gamified approach not only makes the energy harvesting experience more interactive but also introduces a rewarding aspect, fostering a sense of achievement and community participation among users.

The energy sharing feature may allow users to share excess energy generated by the personal energy harvesting system with other users in the same network. This feature can be used to build a community of like-minded individuals who are committed to sustainable living and promote a sharing economy. Further, energy trading marketplace(s) may connects users who have excess energy with those who need more energy, allowing users to monetize their energy generation and utilization. In addition to this, the personal energy harvesting system may enable collaboration with local utility companies to integrate the personal energy harvesting system into the existing smart grid infrastructure, enabling users to sell their excess energy back to the grid and earn credits towards their utility bills.

In some embodiments, the personal energy harvesting system may incorporate sensors that monitor vital health parameters like heart rate, body temperature, and blood oxygen levels, providing users with real-time health feedback. This feature can also enable health and fitness enthusiasts to track their progress and monitor their performance. Further, the personal energy harvesting system may offer users the option to customize their wearables, allowing them to personalize the look and feel of the devices to match their individual style preferences.

The personal energy harvesting system may further include a feature that allows users to use the stored energy in supercapacitors as an emergency power backup in case of power outages or other emergency situations. Further, energy conversion modules may be provided, allowing users to convert the harvested energy into other forms of energy, such as heat or light, to power other devices or appliances. In addition to this, the personal energy harvesting system may introduce a feature that allows users to transfer energy wirelessly between their personal energy harvesting system wearables. For example, users can transfer energy from a wristband 200 (as shown in FIG. 1B) to a smartwatch, eliminating the need for additional charging cables.

Further, in an example, an example personal energy harvesting system may include an umbrella 300, a shoe 400, or a pet saddle 500, as shown in FIG. 1C-1E. This innovative extension of the system's application demonstrates its versatility and adaptability to seamlessly integrate into various facets of daily life. For instance, the incorporation of energy harvesting technology into an umbrella suggests the potential for harnessing ambient energy from movements or changes in environmental conditions. Likewise, embedding the system into a shoe opens possibilities for capturing energy from walking or running, while a pet saddle presents an intriguing avenue for energy harvesting associated with pet activities. This broadening scope showcases the system's capacity to transcend conventional applications, offering a holistic and integrated approach to energy harvesting across a spectrum of items and activities.

By incorporating the above features, a comprehensive and versatile personal energy harvesting system can be provided that meets the evolving needs and preferences of users.

As above, the personal energy harvesting system may be used in a variety of applications. Particularly, as above, the wearable may include (but is not limited to) other types of hats, scarves, necklaces or chest worn devices, gloves, ear warmers, headbands, leggings or pants, suspenders, harnesses, eyeglasses or sunglasses, knee braces, elbow braces, swimsuits or wetsuits, shoulder or chest straps, umbrellas (wearable or hands-free attached to a harness), earmuffs or headphones, gaiters, posture support braces, pet collars, corresponding owner bracelets, pet harnesses, corresponding owner's belt, pet vests, corresponding owners jackets, pet leashes, corresponding owners wristbands, pet booties, corresponding owner shoes, pet saddles, corresponding owner's backpack, etc.

In embodiments wherein the wearable includes a hat or cap, as shown in FIG. 1A, the hat may incorporate flexible solar panels on the top or brim thereof to harness solar energy. Thermoelectric generators may be placed in an inner lining of the hat or cap 100 to capture body heat from the head of the user, while kinetic generators may be integrated into the design to capture energy from head movements of the user. The hat may include an energy storage unit 102, power management system (not shown in FIGURE), and a charging module 104 for electronic devices.

In embodiments wherein the wearable includes a scarf, the scarf may integrate flexible solar panels on an outer surface thereof to capture solar energy. Thermoelectric generators may be placed on the inner surface, in contact with the neck, to capture body heat. Kinetic generators may be strategically placed to capture energy from the user's movements while walking or running. The scarf may feature an energy storage unit, power management system, and a charging module for electronic devices.

In embodiments where the wearable takes the form of necklaces and/or chestworn devices, specific design considerations are implemented to optimize energy harvesting. For instance, small solar panels may be seamlessly integrated into the outer surface of these wearables, harnessing ambient light to generate electricity. Simultaneously, on the inner surface in direct contact with the user's skin, thermoelectric generators may be incorporated to capture body heat and convert it into electrical energy. Additionally, kinetic generators are designed to capture energy generated from the user's body movements, adding another layer of efficiency to the energy harvesting process.

The necklaces and/or chestworn devices are not merely energy harvesters; they are equipped with a comprehensive energy management system. This includes an energy storage unit, ensuring efficient storage of the generated electricity. A power management system is in place to regulate the distribution and consumption of stored energy. Furthermore, a charging module is integrated to facilitate the convenient charging of electronic devices directly from the energy stored in these wearables. This holistic design approach ensures that the energy harvested from various sources is not only efficiently captured but also intelligently managed and made accessible for practical use, enhancing the overall functionality and utility of the wearable devices.

In embodiments wherein the wearable includes gloves, flexible solar panels may be integrated on the outer surface, the thermoelectric generators may be integrated on the inner surface in contact with the skin, and kinetic generators may capture energy from finger movements. The gloves may include an energy storage unit, power management system, and a charging module for electronic devices.

In embodiments wherein the wearable includes ear warmers or headbands, the flexible solar panels may integrate on the outer surface, the thermoelectric generators may integrate on the inner surface in contact with the skin, and kinetic generators may capture energy from head movements. The ear warmers or headbands may feature an energy storage unit, power management system, and a charging module for electronic devices.

In embodiments wherein the wearable includes leggings or pants, the flexible solar panels may be incorporated into the outer surface, thermoelectric generators may be integrated on the inner surface in contact with the skin, and kinetic generators may capture energy from leg movements. The leggings or pants may include an energy storage unit, power management system, and a charging module for electronic devices.

In embodiments wherein the wearable includes suspenders or a harness, solar panels may be integrated into the outer surface, thermoelectric generators may be integrated on the inner surface in contact with the skin, and kinetic generators may capture energy from body movements. The suspender or harness may include an energy storage unit, power management system, and a charging module for electronic devices.

In embodiments wherein the wearable includes eyeglasses or sunglasses, small solar panels may be incorporated onto the frame or arms, thermoelectric generators may be integrated on the inner surface in contact with the skin, and kinetic generators may capture energy from head movements. The eyeglasses or sunglasses may feature an energy storage unit, power management system, and a charging module for electronic devices.

In embodiments wherein the wearable includes knee or elbow braces, flexible solar panels may be integrated on the outer surface, thermoelectric generators may be integrated on the inner surface in contact with the skin, and kinetic generators may capture energy from joint movements. The brace may include an energy storage unit, power management system, and a charging module for electronic devices.

In embodiments wherein the wearable includes swimsuits or wetsuits, flexible solar panels may be incorporated on the outer surface, thermoelectric generators may be integrated on the inner surface in contact with the skin, and water-activated kinetic generators may capture energy from swimming movements. The swimsuits or wetsuits may include a waterproof energy storage unit, power management system, and a charging module for water-resistant electronic devices.

In embodiments wherein the wearable includes shoulder or chest straps, solar panels may be integrated on the outer surface, thermoelectric generators may be integrated on the inner surface in contact with the skin, and kinetic generators may capture energy from body movements. The strap may include an energy storage unit, power management system, and a charging module for electronic devices.

In embodiments wherein the wearable includes umbrellas, flexible solar panels may be incorporated on the outer surface, thermoelectric generators may be placed on the harness in contact with the user's body, and kinetic generators may capture energy from the user's movements while walking. The umbrella may feature an energy storage unit, power management system, and a charging module for electronic devices.

In embodiments wherein the wearable includes earmuffs or headphones, flexible solar panels may be integrated on the outer surface, thermoelectric generators may be integrated on the inner surface in contact with the skin, and kinetic generators may capture energy from head movements. The earmuffs or headphones may include an energy storage unit, power management system, and a charging module for electronic devices.

In embodiments wherein the wearable includes gaiters (worn around the lower leg and ankle), flexible solar panels may be incorporated on the outer surface, thermoelectric generators may be integrated on the inner surface in contact with the skin, and kinetic generators may capture energy from leg movements. The gaiters may include an energy storage unit, power management system, and a charging module for electronic devices.

In embodiments wherein the wearable includes posture support braces, solar panels may be integrated on the outer surface, thermoelectric generators may be integrated on the inner surface in contact with the skin, and kinetic generators may capture energy from body movements. The brace may include an energy storage unit, power management system, and a charging module for electronic devices.

In embodiments wherein the wearables include a pet collar and a corresponding owner bracelet, the pet collar may incorporate flexible solar panels on the outer surface, thermoelectric generators may be incorporated on the inner surface in contact with the pet's skin, and kinetic generators may capture energy from the pet's movements. The collar may include an energy storage unit, power management system, and a charging module for pet trackers or other electronic devices. The owner may have a matching bracelet with similar energy-harvesting technologies to power their devices.

In embodiments wherein the wearables include a pet harness and a corresponding owner's belt, the pet harness may integrate solar panels on the outer surface, thermoelectric generators may be integrated on the inner surface in contact with the pet's skin, and kinetic generators may capture energy from the pet's movements. The harness may feature an energy storage unit, power management system, and a charging module for electronic devices. The owner could wear a complementary belt with similar energy-harvesting features.

In embodiments wherein the wearables include a pet vest and a corresponding owner's jacket, the pet vest may incorporate flexible solar panels on the outer surface, thermoelectric generators may be incorporated on the inner surface in contact with the pet's skin, and kinetic generators may capture energy from the pet's movements. The vest may include an energy storage unit, power management system, and a charging module for electronic devices. The owner could have a matching jacket with similar energy-harvesting technologies.

In embodiments wherein the wearables include a pet leash and a corresponding owner's wristband, the pet leash may integrate solar panels and kinetic generators along the length of the leash, capturing energy from the movement of the leash during walks. The leash handle may have an energy storage unit, power management system, and a charging module for electronic devices. The owner may wear a wristband with thermoelectric generators that capture body heat for additional energy generation.

In embodiments wherein the wearables include pet booties and corresponding owner shoes, the pet booties may incorporate flexible solar panels on the outer surface, thermoelectric generators may be incorporated on the inner surface in contact with the pet's paws, and kinetic generators may capture energy from the pet's movements. The booties may feature an energy storage unit, power management system, and a charging module for electronic devices. The owner may have matching shoes with similar energy-harvesting technologies.

In embodiments wherein the wearables include a pet saddle and a corresponding owner's backpack (e.g., for horse owners), the pet saddle may integrate solar panels on the outer surface, thermoelectric generators may be integrated on the inner surface in contact with the horse's skin, and kinetic generators may capture energy from the horse's movements. The saddle may include an energy storage unit, power management system, and a charging module for electronic devices. The owner may wear a backpack with similar energy-harvesting features.

These wearable options for pets and their owners offer innovative ways to integrate solar, thermoelectric, and kinetic energy sources, providing eco-friendly solutions for powering electronic devices for both pets and humans. As above, it should be appreciated that the wearable is not limited to the example embodiments given above.

In addition to the previously mentioned components, the personal energy harvesting system includes a vital feature: an energy management system seamlessly integrated into the at least one storage device. This energy management system serves a crucial role in overseeing and controlling the distribution and consumption of the electricity generated and stored by the system. Acting as a sophisticated controller, the energy management system ensures an optimized and efficient utilization of the stored energy, enhancing the overall performance of the personal energy harvesting system.

By regulating the flow of electricity within the system, the energy management system strategically allocates the stored energy based on demand, environmental conditions, and user preferences. This capability not only maximizes the availability of electricity for various applications but also contributes to the system's adaptability and sustainability. Users can benefit from a consistent and reliable source of power for their electronic devices, while the energy management system intelligently navigates the dynamic energy requirements, thereby enhancing the user experience and promoting responsible energy consumption practices.

Within the personal energy harvesting system, a pivotal element is the charging module, which is equipped with advanced capabilities. This module incorporates adaptive charging algorithms, representing a sophisticated technology that empowers the system to dynamically tailor its charging parameters. This dynamic adjustment is based on several crucial factors, including the prevailing energy storage conditions within the system, the specific specifications of the connected electronic device, and real-time environmental factors.

The adaptive charging algorithms play a key role in optimizing the charging process by continuously assessing and responding to the system's internal state and external conditions. For instance, if the energy storage level is high, the adaptive algorithms may adjust the charging rate to prevent overcharging and enhance energy efficiency. Similarly, when connecting different electronic devices with varying power requirements, the charging module adapts its parameters to ensure compatibility and efficient energy transfer.

Moreover, the real-time consideration of environmental factors adds another layer of intelligence to the adaptive charging process. The system can respond to variations in ambient conditions, such as changes in light intensity or temperature, to further refine the charging process. This adaptability ensures that the personal energy harvesting system operates optimally in diverse and dynamic settings, providing users with an efficient, versatile, and user-friendly solution for charging their electronic devices.

The at least one energy harvesting device: a self-adjusting mechanism. This mechanism represents a sophisticated technology that endows the system with the ability to dynamically optimize the efficiency of energy capture. The self-adjusting mechanism operates by continuously monitoring and responding to two crucial factors—the user's activity levels and the prevailing environmental conditions.

The dynamic optimization process begins with the self-adjusting mechanism assessing the user's activity levels, such as movements, body heat, and interaction with the environment. By gauging these activity levels, the system gains insights into the amount of energy that can be harnessed in real-time. Subsequently, the mechanism intelligently adjusts the sensitivity and configuration of the energy harvesting components embedded in the wearable device.

This adjustment process is finely tuned to the user's immediate requirements. For instance, during periods of heightened activity, the self-adjusting mechanism may increase the sensitivity of the energy harvesting components to capture more energy efficiently. Conversely, in moments of lower activity, the sensitivity may be dialed down to conserve energy. This adaptive capability ensures that the personal energy harvesting system maximizes its performance in response to the user's dynamic energy needs and the ever-changing environmental context.

By incorporating this self-adjusting mechanism, the personal energy harvesting system not only enhances its overall efficiency but also optimizes user experience by seamlessly aligning energy capture with real-world conditions.

Some of the non-limiting advantages of the present invention are:
Renewable Energy Generation: The proposed invention harnesses energy from various sources such as body heat, movement, and ambient light through integrated wearables, providing users with a renewable and sustainable energy generation solution.
Reduced Environmental Impact: By enabling users to generate electricity from their everyday movements, the personal energy harvesting system significantly reduces reliance on traditional, non-renewable energy sources. This reduction contributes to minimizing users' carbon footprints and mitigating environmental degradation.
Versatile Wearable Integration: The invention demonstrates a diverse range of wearable embodiments, including necklaces, pants, suspenders, eyeglasses, and more. This versatility allows users to seamlessly integrate energy harvesting technology into their daily attire, enhancing user adaptability and comfort.
Real-time Monitoring and Optimization: Incorporating IoT technology and AI algorithms, the system connects to a smartphone application, enabling users to monitor their energy generation, storage, and usage in real-time. Personalized recommendations optimize energy harvesting and consumption patterns based on individual habits, fostering awareness and responsible energy use.
Community Engagement and Economic Benefits: The inclusion of features like energy sharing among users, participation in energy trading marketplaces, and collaboration with utility companies establishes a sense of community engagement. Users can share surplus energy, monetize their generation, and even earn credits by selling excess energy back to the grid, providing economic incentives for sustainable energy practices.

The exact specifications, materials used, and method of use of the personal energy harvesting system may vary upon manufacturing.

The foregoing descriptions of specific embodiments of the present invention have been presented for purposes of illustration and description. They are not intended to be exhaustive or to limit the present invention to the precise forms disclosed, and obviously many modifications and variations are possible in light of the above teaching. The exemplary embodiments were chosen and described in order to best explain the principles of the present invention and its practical application, to thereby enable others skilled in the art to best utilize the present invention and various embodiments with various modifications as are suited to the particular use contemplated.

What is claimed is:

1. A personal energy harvesting system, comprising:
at least one kinetic energy harvester configured to integrate a piezoelectric material and graphene, thereby converting mechanical energy into electrical energy;
at least one thermoelectric generator including graphene to convert thermal energy into electrical energy; and
at least one solar panel including graphene to convert solar energy into electrical energy, wherein
wherein the graphene, integrated into each energy harvester, serves to enhance both electrical conductivity and mechanical durability, collectively optimizing the efficiency and robustness of the overall energy harvesting system.

2. An energy storage device for a personal energy harvesting system, comprising:
a supercapacitor incorporating graphene electrodes, exhibiting a high surface area, configured to store electrical energy harvested from at least one of a kinetic energy harvester employing a piezoelectric material and graphene, a thermoelectric generator comprising graphene to convert thermal energy into electrical energy, and a solar panel including graphene for converting solar energy into electrical energy, and
wherein the supercapacitor is integrated into a wearable item within the personal energy harvesting system to provide stored electrical energy to at least one electronic device.

3. The personal energy harvesting system of claim 1, wherein the at least one kinetic energy harvester comprises a combination of flexible solar panels, thermoelectric generators, and kinetic generators integrated into the wearable.

4. The personal energy harvesting system of claim 1, further comprising AI integration, wherein AI algorithms optimize energy harvesting and usage based on individual user preferences, routines, and lifestyle patterns.

5. The personal energy harvesting system of claim 1, further comprises an energy management system within the at least one storage device to regulate distribution and consumption of the stored generated electricity.

6. The personal energy harvesting system of claim 1, comprises a charging module incorporating adaptive charging algorithms, enabling it to dynamically adjust charging parameters based on the energy storage conditions, electronic device specifications, and real-time environmental factors.

7. The personal energy harvesting system of claim 1, wherein the at least one kinetic energy harvester further comprises a self-adjusting mechanism, wherein the system dynamically optimizes energy capture efficiency by adjusting the sensitivity and configuration of the energy harvesting components based on the user's activity levels and environmental conditions.

8. The personal energy harvesting system of claim 1, wherein the wearable item comprises one or more selected from the group consisting of wristbands, clothing, shoes, necklaces, chestworn devices, leggings, pants, suspenders, harnesses, eyeglasses, sunglasses, knee braces, elbow braces, swimsuits, wetsuits, shoulder straps, chest straps, umbrellas, earmuffs, headphones, gaiters, posture support braces, pet collars with corresponding owner bracelets, pet harnesses with corresponding owner's belts, pet vests with corresponding owner's jackets, pet leashes with corresponding owner's wristbands, pet booties with corresponding owner shoes, pet saddles with corresponding owner's backpacks.

9. A wearable item for energy harvesting and storage of personal energy harvesting system of claim 1, comprising:
an item of clothing or accessory integrating the energy harvesting system and the energy storage device wherein the wearable item includes graphene-enhanced fibers.

10. A system for monitoring and managing energy in a personal energy harvesting system of claim 1, comprising:
an IoT connectivity module configured to communicate with the energy harvesting system and the energy storage device;
a software application to receive data from the IoT connectivity module, offering user interface functionality for monitoring and managing the storage and usage of energy within the personal energy harvesting system.

11. A modular personal energy harvesting system of claim 1, comprising:
interchangeable energy harvesting modules; and
interchangeable energy storage devices, wherein modular components are configured to be user-replaceable and customizable based on individual energy requirements.

12. A method for producing a graphene-integrated component for a personal energy harvesting system of claim 1, comprising:
synthesizing graphene through chemical vapor deposition (CVD);
integrating the synthesized graphene into the components of the energy harvesting system and the energy storage device.
